(19) United States
(12) Patent Application Publication
(10) Pub. No.: US 2026/0229844 A1
(43) Pub. Date: Aug. 6, 2026

(54) OUTPUT MODULE FOR HIGH-POWER EXTERNAL-CAVITY TUNABLE QUANTUM CASCADE LASER

(71) Applicant: Beijing University of Technology, Beijing (CN)

(72) Inventors: Wenbin QIN, Beijing (CN); Kuikui LI, Beijing (CN); Menghua JIANG, Beijing (CN); Youqiang LIU, Beijing (CN); Zhiyong WANG, Beijing (CN)

(73) Assignee: Beijing University of Technology, Beijing (CN)

(21) Appl. No.: 19/578,520

(22) Filed: Mar. 25, 2026

(30) Foreign Application Priority Data
Sep. 17, 2025 (CN) 202511326846.9

(51) Int. Cl. H01S 5/14; G02B 5/18; G02B 5/30; H01S 3/08; H01S 5/34; H01S 5/40

(52) U.S. Cl. CPC H01S 5/141; H01S 3/08054; H01S 5/3402; H01S 5/4012; G02B 5/1866; G02B 5/3058; G02B 5/3083

(57) ABSTRACT

An output module for a high-power external-cavity tunable quantum cascade laser is provided, comprising: a first lens, a first half-wave plate and a first mid-infrared wire-grid polarizer successively arranged along an optical path of a first laser; a second lens, a second half-wave plate, a second mid-infrared wire-grid polarizer and a third half-wave plate successively arranged along an optical path of a second laser; wherein the emergent lights of the first mid-infrared wire-grid polarizer and the third half-wave plate converge on different surfaces of the third mid-infrared wire-grid polarizer, respectively. The present disclosure addresses the problems of wavelength locking instability and low polarization beam combining efficiency, which are caused by the insufficient polarization state in the quantum cascade laser. It enables narrow-linewidth output and wavelength tuning of the quantum cascade laser. Furthermore, through an expanded polarization beam combining structure, it can even achieve high-power, dual-wavelength tunable output.

### TECHNICAL FIELD

The present disclosure relates to the field of semiconductor laser technology, particularly to an output module for a high-power external-cavity tunable quantum cascade laser.

### BACKGROUND

Since the successful development by Faist et al. at Bell Laboratories, quantum cascade lasers have been a focus of researchers. This is because, compared to conventional semiconductor lasers, they can achieve laser output in the mid-infrared to terahertz bands by utilizing an optical emission process that is independent of the semiconductor's bandgap. Notably, they cover two important atmospheric windows of 3-5 μm and 8-12 μm, granting them significant application value in areas such as free-space communication and trace gas detection. However, most conventional quantum cascade lasers exhibit multi-longitudinal-mode output and suffer from low output power, which makes it difficult to meet the demands of practical applications. Consequently, it puts forward new requirements on the power, linewidth, and tuning range of quantum cascade lasers.

Currently, wavelength tuning is achieved primarily through three methods: distributed Bragg reflector (DBR) gratings, distributed feedback (DFB) gratings, and external-cavity tuning. The external-cavity feedback quantum cascade laser is less dependent on stringent design requirements for the light source itself. This method is capable of providing both single-longitudinal-mode and wide-tuning-range laser output, thereby fulfilling the aforementioned requirements. A typical external-cavity feedback quantum cascade laser may be categorized into either a Littrow structure (as shown in FIG. 5) or a Littman structure. The Littman structure incorporates an additional mirror compared to the Littrow structure. While this allows for obtaining a narrower linewidth, it also results in an increased loss.

Nevertheless, the quantum cascade lasers exhibit low power and a degree of polarization less than 100% (as shown in FIG. 4, the output beam is not completely polarized, and depolarization can occur under high-current conditions, which is incompatible with the polarimetric properties of blazed gratings), which is detrimental to subsequent power scaling and restricts the further application of this technology.

Accordingly, the present disclosure is proposed.

### SUMMARY

An objective of the present disclosure is to provide an output module for a high-power external-cavity tunable quantum cascade laser. This module is configured to effectively address the problems of wavelength locking instability and low polarization beam combining efficiency, which is caused by the insufficient polarization state in the quantum cascade laser. Furthermore, through an expanded polarization beam combining structure, a high-power, dual-wavelength tunable output is achieved.

The present disclosure provides an output module for a high-power external-cavity tunable quantum cascade laser, including: a first laser, wherein a first lens, a first half-wave plate and a first mid-infrared wire-grid polarizer are successively arranged along an optical path of the first laser; a second laser, wherein a second lens, a second half-wave plate, a second mid-infrared wire-grid polarizer and a third half-wave plate are successively arranged along an optical path of the second laser; and a third mid-infrared wire-grid polarizer, wherein emergent lights of the first mid-infrared wire-grid polarizer and the third half-wave plate converge on different surfaces of the third mid-infrared wire-grid polarizer, respectively.

Further, by setting an inclination angle for the third mid-infrared wire-grid polarizer, a beam combination is achieved by combining a transmitted light that is the emergent light from the first mid-infrared wire-grid polarizer and that passes through the third mid-infrared wire-grid polarizer with a reflected light that is the emergent light from the third half-wave plate and that is reflected on the surface of the third mid-infrared wire-grid polarizer.

Further, a first blazed grating and a second blazed grating are further included, wherein the first blazed grating is arranged on a reflection optical path of the first mid-infrared wire-grid polarizer, and the second blazed grating is arranged on a reflection optical path of the second mid-infrared wire-grid polarizer.

Further, mounting angles of the first blazed grating and the second blazed grating are both adjustable.

Further, blaze angles of the blazed gratings are placed at a Littrow angle.

Further, the first laser and the second laser are both quantum cascade lasers.

Further, the first laser and the second laser are mounted on an anodized aluminum substrate, and an indium sheet is disposed between bottom surfaces of lasers and the aluminum substrate.

Further, the first lens and the second lens are both aspherical lenses.

Further, both surfaces of the first lens and the second lens are coated with an antireflection film.

Further, the first half-wave plate, the second half-wave plate, and the third half-wave plate are rotatable half-wave plates.

The technical solution of the present disclosure is as follows: the beam emitted by the first laser is collimated by the first lens and is directed into the first half-wave plate, which is positioned preceding the first mid-infrared wire-grid polarizer, to adjust the P-polarized light (TM) and S-polarized light (TE) components within the beam. As this beam enters the first mid-infrared wire-grid polarizer, the S-polarized light undergoes total reflection at the polarization-separation film and cannot pass through, while the P-polarized light is transmitted directly, and is directed into the third mid-infrared wire-grid polarizer. Separately, the beam emitted by the second laser is collimated by the second lens. Polarization separation is similarly achieved using the second mid-infrared wire-grid polarizer. The P-polarized light is converted into S-polarized light by the third half-wave plate located on an output path of the P-polarized light. Subsequently, the P-polarized light from the first mid-infrared wire-grid polarizer is transmitted through the third mid-infrared wire-grid polarizer, while the S-polarized light from the third half-wave plate is reflected by the third mid-infrared wire-grid polarizer. This configuration causes the polarization beam combining to be performed on the third mid-infrared wire-grid polarizer, thereby yielding a high-power output beam.

### BRIEF DESCRIPTION OF THE DRAWINGS

To explain the embodiments of the present disclosure or the technical solutions in the prior art more clearly, a brief introduction will be made to the accompanying drawings used in the embodiments or the description of the prior art. It is obvious that the drawings in the description below are only some embodiments of the present disclosure, and those ordinarily skilled in the art can obtain other drawings according to these drawings without creative work.

FIG. 1 is a schematic view of an overall structure of the present disclosure;

FIG. 2 is a schematic view of an aspherical lens of the present disclosure;

FIG. 3 is a schematic view of a polarization beam combining of two lasers of the present disclosure;

FIG. 4 is a schematic view of a conventional polarization beam combining in the background art;

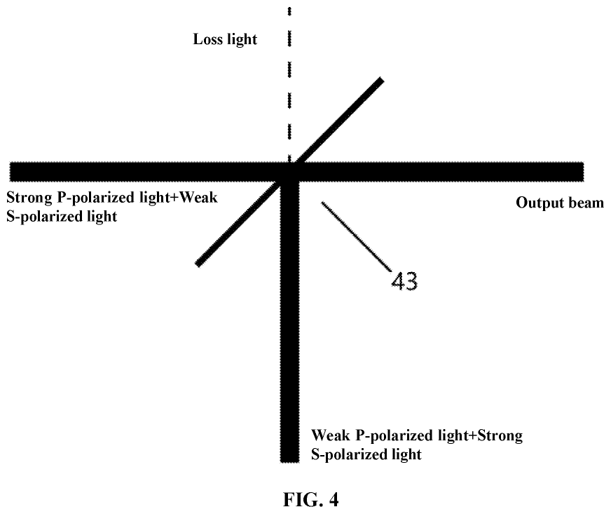

FIG. 5 is a schematic view of a structure of a conventional Littrow external-cavity tunable quantum cascade laser in the background art;

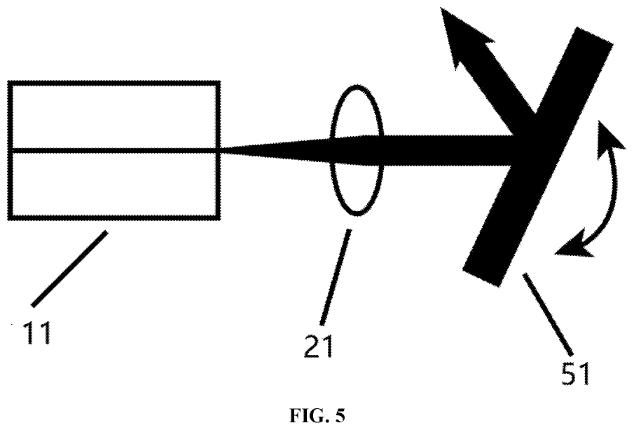

### REFERENCE NUMERALS IN FIGURES

11—a first laser; 12—a second laser;
21—a first lens; 22—a second lens;
31—a first half—wave plate; 32—a second half-wave plate; 33—a third half-wave plate;
41—a first mid-infrared wire-grid polarizer; 42—a second mid-infrared wire-grid polarizer; 43—a third mid-infrared wire-grid polarizer;
51—a first blazed grating; 52—a second blazed grating.

### DETAILED DESCRIPTION OF THE EMBODIMENTS

The following clearly and completely describes the technical solutions in embodiments of the present disclosure with reference to the embodiments of the present disclosure. Apparently, the described embodiments are only some but not all of the embodiments of the present disclosure. All other embodiments obtained by those of ordinary skill in the art based on the embodiments of the present disclosure without involving any creative effort shall fall within the scope of protection of the present disclosure.

In the above description of the present disclosure, it is to be noted that the orientation or positional relationship indicated by terms “center,” “longitudinal,” “transverse,” “length,” “width,” “thickness,” “upper,” “lower,” “front,” “rear,” “left,” “right,” “vertical,” “horizontal,” “top,” “bottom,” “inner,” “outer,” “clockwise,” and “counterclockwise”, etc. is based on the orientation or positional relationship shown in the accompanying drawings, merely for ease of description and simplification of the description of the present disclosure, and not to indicate or imply that the referenced device or element must have a particular orientation and be constructed and operative in a particular orientation, and thus may not be construed as a limitation on the present disclosure.

Furthermore, the terms “first” and “second” are used for descriptive purposes only and are not to be construed as indicating or implying relative importance or implicitly specifying the quantity of the indicated technical features. Thus, features defined with “first” or “second” may explicitly or implicitly include one or more of such features. In the description of the present disclosure, the term “a plurality of” means two or more, unless expressly specified otherwise. Additionally, the terms “arrangement”, “mounting” and “connection” should be understood in a broad sense, for example, they may be a fixed connection, a detachable connection, or an integrated connection; may be a mechanical connection, or an electrical connection; and may be a direct connection, or an indirect connection via an intermediate medium, or communication inside two elements. For those of ordinary skill in the art, the specific meanings of the above terms in the present disclosure may be understood according to specific circumstances.

### Embodiment 1

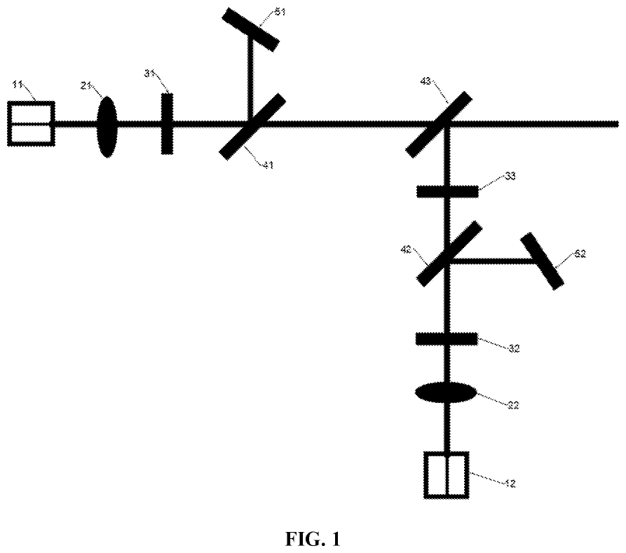

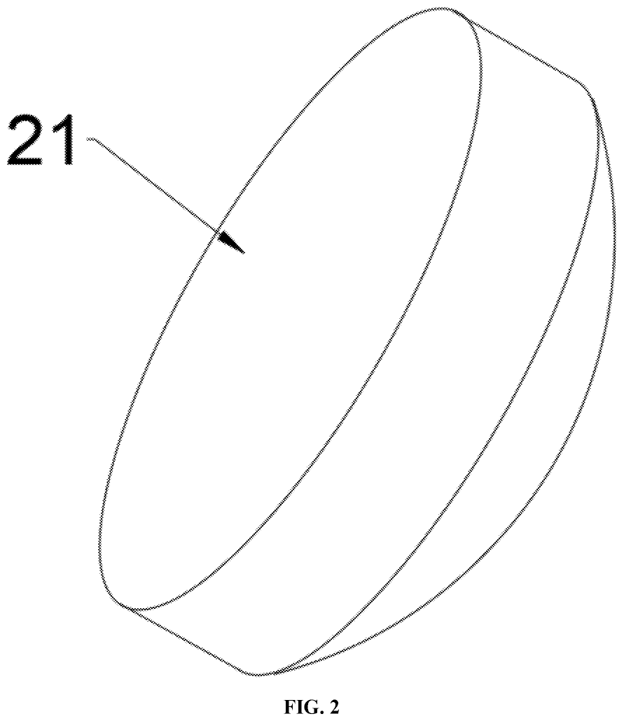

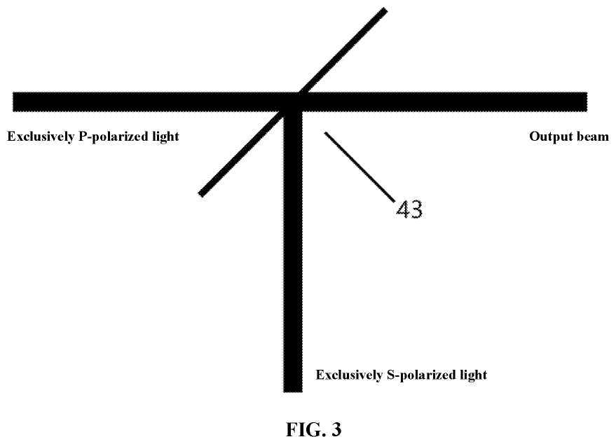

As shown in FIGS. 1-3, the present disclosure provides the output module for a high-power external-cavity tunable quantum cascade laser, including: the first laser 11, wherein the first lens 21, the first half-wave plate 31 and the first mid-infrared wire-grid polarizer 41 are successively arranged along the optical path of the first laser 11; the second laser 12, wherein the second lens 22, the second half-wave plate 32, the second mid-infrared wire-grid polarizer 42 and the third half-wave plate 33 are successively arranged along the optical path of the second laser 12; and the third mid-infrared wire-grid polarizer 43, wherein the emergent lights of the first mid-infrared wire-grid polarizer 41 and the third half-wave plate 33 converge on different surfaces of the third mid-infrared wire-grid polarizer 43, respectively.

The angle of the third mid-infrared wire-grid polarizer 43 is set, so that beam combining is achieved by transmitting the light from the first mid-infrared wire-grid polarizer 41 and reflecting the light from the third half-wave plate 33. The mid-infrared wire-grid polarizer uses silicon as a substrate and is employed to effect polarization separation and beam combination.

The first blazed grating 51 and the second blazed grating 52 are further included, wherein the first blazed grating 51 is arranged on the reflected optical path of the first mid-infrared wire-grid polarizer 41, and the second blazed grating 52 is arranged on the reflected optical path of the second mid-infrared wire-grid polarizer 42. The first blazed grating 51 and the second blazed grating 52 are mounted with an adjustable angle. The blaze angle of each blazed grating is optimized at the central wavelength band of the quantum cascade laser, and the blaze angle of the blazed grating is placed at the Littrow angle to constitute an optical feedback channel. A blazed grating is employed for wavelength locking and wavelength tuning of a quantum cascade laser. For the S-polarized light, the S-polarized light cannot transmit through the polarization-separation film, it undergoes total reflection at the mid-infrared wire-grid polarizer and enters a blazed grating placed at the Littrow angle to form optical feedback. This feedback narrows the linewidth, provides a high side-mode suppression ratio, and allows the selected wavelength to be changed by adjusting the grating angle. By fixing the angle of one grating and adjusting the angle of the other blazed grating, a high-power, dual-wavelength tunable output can be achieved.

The first laser 11 and the second laser 12 are both quantum cascade lasers. The quantum cascade laser is packaged by using a Window package, and is mounted on an anodized aluminum substrate, and an indium sheet is disposed between bottom surfaces of lasers and the aluminum substrate, so as to sufficiently dissipate heat.

The first lens 21 and the second lens 22 are both aspherical lenses. The aspherical lens can minimize spherical aberration, and both surfaces of the aspherical lens (the first lens 21 and the second lens 22) are coated with a corresponding antireflection film.

The first half-wave plate 31, the second half-wave plate 32 and the third half-wave plate 33 are rotatable half-wave plates. A rotatable half-wave plate, also termed a phase retarder, can produce a certain phase retardation for the light of two polarization states in the beam, and change the polarization state of the beam by changing the angle between the optical axis and the direction of the electric field of the output beam.

The working principle of the present disclosure is as follows:

The beam emitted by the first laser 11 (quantum cascade laser) is collimated by the first lens 21 (aspherical lens), and is directed into the first half-wave plate 31 (rotatable half-wave plate), which is positioned preceding the first mid-infrared wire-grid polarizer 41, to adjust the P-polarized light and S-polarized light components/proportions in the beam by rotating the half-wave plate. As the beam enters the first mid-infrared grating polarizer 41, the mid-infrared grating polarizer has the functions of polarization separation and polarization beam combination. For the S-polarized light, the S-polarized light cannot transmit through the polarization-separation film, it undergoes total reflection at the mid-infrared wire-grid polarizer and enters the first blazed grating 51 placed at the Littrow angle to form optical feedback. This feedback narrows the linewidth, provides a high side-mode suppression ratio, and allows the selected wavelength to be changed by adjusting the grating angle. While the P-polarized light is transmitted directly, and is again incident and transmitted through the third mid-infrared wire-grid polarizer 43.

Similarly, after the beam emitted by the second laser 12 (quantum cascade laser) is collimated by the second lens 22 (aspherical lens), the polarization separation is similarly achieved using the second mid-infrared wire-grid polarizer 42. The S-polarized light is totally reflected and directed toward the second blazed grating 52 at the Littrow angle for external-cavity feedback. Unlike the previous configuration, and to meet the requirements of polarization beam combination, the third half-wave plate 33 (rotatable half-wave plate) is inserted into the output path of the P-polarized light to convert the P-polarized light into S-polarized light. Consequently, a high-power output is obtained by performing polarization beam combination in the polarization plane with the P-polarized light that has been transmitted through the first mid-infrared grating polarizer 41 and the third mid-infrared grating polarizer 43.

Additionally, by fixing the angle of one grating and adjusting the angle of the other, a high-power, dual-wavelength tunable output can be achieved.

The present disclosure effectively addresses the problems of wavelength locking instability and low polarization beam combining efficiency, which are caused by the insufficient polarization state in the quantum cascade laser. It enables narrow-linewidth output and wavelength tuning of the quantum cascade laser. Furthermore, through an expanded polarization beam combining structure, it can even achieve high-power, dual-wavelength tunable output.

Finally, it should be noted that the above embodiments are merely used for describing the technical solutions of the present disclosure, rather than limiting the same. Although the present disclosure has been described in detail with reference to the preferred examples, those of ordinary skill in the art should understand that the technical solutions of the present disclosure may still be modified or equivalently replaced, or replace some or all of the technical features with equivalents. However, these modifications or substitutions should not cause the corresponding technical solutions to deviate from the scope of the technical solutions of the embodiments of the present disclosure.

What is claimed is:

1. An output module for a high-power external-cavity tunable quantum cascade laser, comprising:
a first laser, wherein a first lens, a first half-wave plate and a first mid-infrared wire-grid polarizer are successively arranged along an optical path of the first laser;
a second laser, wherein a second lens, a second half-wave plate, a second mid-infrared wire-grid polarizer and a third half-wave plate are successively arranged along an optical path of the second laser;
and a third mid-infrared wire-grid polarizer, wherein emergent lights of the first mid-infrared wire-grid polarizer and the third half-wave plate converge on different surfaces of the third mid-infrared wire-grid polarizer;
wherein by setting an inclination angle for the third mid-infrared wire-grid polarizer, a beam combination is achieved by combining a transmitted light that is the emergent light from the first mid-infrared wire-grid polarizer and that passes through the third mid-infrared wire-grid polarizer with a reflected light that is the emergent light from the third half-wave plate and that is reflected on the surface of the third mid-infrared wire-grid polarizer;
wherein the output module further comprises a first blazed grating and a second blazed grating, wherein the first blazed grating is arranged on a reflection optical path of the first mid-infrared wire-grid polarizer, and the second blazed grating is arranged on a reflection optical path of the second mid-infrared wire-grid polarizer.

2. The output module for a high-power external-cavity tunable quantum cascade laser according to claim 1, wherein mounting angles of the first blazed grating and the second blazed grating are both adjustable.

3. The output module for a high-power external-cavity tunable quantum cascade laser according to claim 2, wherein blaze angles of the blazed gratings are placed at a Littrow angle.

4. The output module for a high-power external-cavity tunable quantum cascade laser according to claim 1, wherein the first laser and the second laser are both quantum cascade lasers.

5. The output module for a high-power external-cavity tunable quantum cascade laser according to claim 4, wherein the first laser and the second laser are mounted on an anodized aluminum substrate, and an indium sheet is disposed between bottom surfaces of lasers and the aluminum substrate.

6. The output module for a high-power external-cavity tunable quantum cascade laser according to claim 1, wherein the first lens and the second lens are both aspherical lenses.

7. The output module for a high-power external-cavity tunable quantum cascade laser according to claim 6, wherein both surfaces of the first lens and the second lens are coated with an antireflection film.

8. The output module for a high-power external-cavity tunable quantum cascade laser according to claim 1, wherein the first half-wave plate, the second half-wave plate, and the third half-wave plate are rotatable half-wave plates.
